(19) United States
(12) Patent Application Publication
(10) Pub. No.: US 2023/0259662 A1
(43) Pub. Date: Aug. 17, 2023

(54) MODELING A KARST FORMATION FOR A WELLBORE OPERATION

(71) Applicants: Landmark Graphics Corporation, Houston, TX (US); Petróleo Brasileiro S.A. - Petrobras, Rio de Janeiro (BR)

(72) Inventors: Marcio Rogerio Spinola Pereira, Rio de Janeiro (BR); Erwan Yann Renaut, Rio de Janeiro (BR); Caroline Lessio Cazarin, Rio de Janeiro (BR); Luiz Eduardo Pinheiro Santos, Rio de Janeiro (BR); Franco Borges Quadros, Rio de Janeiro (BR)

(21) Appl. No.: 17/669,902

(22) Filed: Feb. 11, 2022

(51) Int. Cl. G06F 30/10; G06T 17/05; G06T 17/20

(52) U.S. Cl. CPC G06F 30/10; G06T 17/05; G06T 17/20

(57) ABSTRACT

A system can model a karst formation for controlling a wellbore operation. The system can receive first input data that includes a set of fracture properties in a fracture network of a subterranean formation. The system can receive second input data that includes a set of point sets from a fracture geometry of the fracture network. The system can generate a set of fracture skeletons from the first input data and the second input data. The system can model a karst feature based on the plurality of fracture skeletons. The system can output the karst feature for controlling a wellbore operation.

### TECHNICAL FIELD

The present disclosure generally relates to wellbore operations, and more particularly (although not necessarily exclusively), to modeling a karst formation for a wellbore operation.

### BACKGROUND

A wellbore can be formed in a subterranean formation or a sub-oceanic formation for extracting produced hydrocarbon material. A wellbore operation, such as an exploration operation, a drilling operation, and the like, can be performed with respect to the subterranean formation or the sub-oceanic formation. For example, the drilling operation can be performed with respect to the subterranean formation for forming the wellbore to extract produced hydrocarbon material. The performance of the wellbore operation can be influenced by various properties of the subterranean formation or any sub-formations thereof. But, measuring or otherwise determining the various properties may be difficult and may use excessive amounts of resources.

### BRIEF DESCRIPTION OF THE DRAWINGS

FIG. 1 is a perspective view of a karst formation that includes a set of karst features and a reference wellbore according to one example of the present disclosure.

FIG. 2 is a block diagram of a computing system for modeling a karst formation according to some examples of the present disclosure.

FIG. 3 is a flow chart of a process for modeling a karst feature according to one example of the present disclosure.

FIG. 4 is a flow chart of a process for using one or more primitive objects to model a karst formation according to one example of the present disclosure.

FIG. 5 is a flow chart of a process for simulating a karst feature of a karst formation using cross-sections associated with fracture skeletons according to one example of the present disclosure.

FIG. 6 is an example of a modeled result of a primitive object of a karst formation according to one example of the present disclosure.

FIG. 7 is an example of a modeled result of a karst feature of a karst formation using cross-sections according to one example of the present disclosure.

FIG. 8 is an example of a modeled karst feature according to one example of the present disclosure.

FIG. 9 is an example of a modeled karst feature based on a set of triangular meshes according to one example of the present disclosure.

FIG. 10 is an example of a graphical user interface that can be used to model a karst formation according to one example of the present disclosure.

### DETAILED DESCRIPTION

Certain aspects and examples of the present disclosure relate to modeling one or more karst features of a karst formation using geological properties (e.g., fracture properties) associated with the karst formation. The karst formation may be a subterranean formation or may be included in (e.g., a feature of) a subterranean formation. The set of karst features may include vugs, dolines, fractures, and the like that can be included in the karst formation. The geological properties can include a fracture geometry, fracture properties such as aperture, porosity, permeability, etc., and other similar properties relating to a fracture network of the karst formation. A fracture or fracture network can be any separation in a geological formation, such as a joint or a fault that divides rock into two or more pieces. The set of karst features may be modeled with respect to a reference wellbore, a target wellbore, or a combination thereof. The target wellbore can be positioned, or can be planned to be formed, proximate to the reference wellbore within the karst formation.

The set of karst features can be used to predict lost circulation, production, other performance indicators, or any combination thereof with respect to the target wellbore. Additionally, modeling the set of karst features can help mitigate or prevent early water cut during a wellbore operation, such as a drilling operation, with respect to the target wellbore. A fracture will sometimes form a deep fissure or crevice in the rock. In addition, fractures can provide permeability for fluid movements, such as water or hydrocarbons. Fractures in the karst formation area can include features, such as caves, springs, disappearing streams, dry valleys, sinkholes, and the Ike, resulting from acidic groundwater moves through fractures and spaces within the rock, slowly dissolving and enlarging spaces to create larger openings and connected passages. The fracture network can include patterns in several fractures that intersect with each other. The fracture network can be formed when rock is stressed or strained, for example as a result from the forces associated with plate-tectonic activity associated with a karst formation.

Karst features (e.g., of a karst formation) can be modeled using earth modeling to simulate karst geological objects stochastically. The karst geological objects can include vugs, dolines, cave geometries, and the like. In some examples, the modeled karst features may consider both hydrothermal (e.g., hypogenic) and meteoric (e.g., epigenic) karst formations. The result of earth modeling with karst features can include geological objects with geometries represented either by three-dimensional triangular meshes or point sets. The result can be exported to a regular grid for karst feature model-building or fracture skeleton-simulation. Additionally or alternatively, the result can involve an upscaling process. The upscaling process can be applied to epigenic and hypogenic modeling to perform upscaling to a regular grid. The regular grid can include multiple geological objects, such as vugs, caves, or dolines. In another example, the regular grid model can enable geoscientists and engineers to build more realistic and representative models leading to support better decisions on a reservoir management.

The modeled karst features can be adapted to an epigenic or to a hypogenic geometry when considering geological concepts associated with carbonate rocks by modeling and simulating geological objects. Hypogenic karst features can be associated with an earth modeling and simulated fracture network, including fracture properties, and can be used to build or model a three-dimensional network of enlarged fractures that can represent the geometry of dissolved carbonate rocks with cave morphologies (hypogenic caves).

In some examples, earth modeling can involve input well logs, seismic data, interpreted horizons, seismic attributes, geological facies modeling, geo-mechanical models, vertical proportion curves, map proportion curves, observed fracture density, a distribution of dips and azimuth of interpreted fractures, an amount of fractures per length, clustering parametrization, smoothness, and the like. The earth modeling can additionally involve fracture properties, such as aperture, permeability, porosity, center of gravity, distance from edges, and other suitable properties of simulated fractures. Other fracture properties or attributes can also be included in the earth modeling. Additionally, the earth modeling can use a natural fracture network model. In some examples, the earth modeling can also be used from other sources using various formats and continue the workflow to simulate the natural fracture network and model the karst formation.

Additionally or alternatively, the external parameters (i.e., epigenic karst parameters) can be obtained from outcrops, which can be used as an input reference, as well as an exposed, interpreted horizon (e.g., phreatic or paleo water table reference surface) and user-defined geologic objects, such as vugs, dolines, vertical and horizontal passages, geo-statistical distributions, and the like. Moreover, the internal parameters (i.e., hypogenic karst parameters) can be collected automatically from the natural fracture network. The fracture properties (e.g., of the natural fracture network) can influence geometric dissolutions of carbonates in the formation. By using fracture geometry meshes and properties of fractures, karst features can be modeled consistently with respect to development of hypogenic caves or other geometries (e.g., vugs, dolines, etc.). Geological features, objects, scales, and resultant geometries can be defined or otherwise generated through a graphical user interface. Accordingly, the karst features can be represented as point sets or regions in three-dimensional space with a volumetric mesh. Additionally or alternatively, the simulated geological features and objects can also be upscaled to reservoir flow simulators for use in predicting upscaled karst geological objects.

In some examples, two type of caves can be classified by modeling a karst formation. A first type of cave can include epigenic caves, and a second type of cave can be hypogenic caves. The epigenic caves can be formed by an aggressive recharge that descends from the earth surface (e.g., object modeling can be treated in sections below as dolines, vugs, shafts, and connections). In some examples, the epigenic caves can be modeled as a result of different types of architectural elements such as vertical shafts, tubes and groundwater channels, dolines, canyons, caves, sinks holes, fractures, and the like. In some examples, the hypogenic caves can be formed by an aggressive recharge of groundwater that rises under artesian conditions.

Epigenic karst features can be modeled using various techniques. For example, a list of three-dimensional geological objects with specific geometries representing geomorphological shapes delimitating regions in space for vugs, passages, vertical shafts, tubes, dolines, vertical shafts can be modeled, simulated, visualized and stored as volumetric meshes. The geological objects can involve a list of parameters that varies according to object types and generally a range of values describing vertical, horizontal, lateral variations, preferential dip, azimuth, and other suitable parameters. The parameters can be selected by an entity (e.g., a user, a geoscientist, etc.). For each one of the parameters, a maximum and minimum variation can allow the entity to define limits. For instance, nominally regarding vug modeling, parameters can include tree orthogonal axes with maximum and minimum minor radius (e.g., traditional direction y), major radius (e.g., traditional direction x), Rz radius (vertical direction), dip, and azimuth. For the doline geological object, the parameters can include the top entrance (top radius) bottom radius, length, and shape factor, etc. For modeling vertical shafts or horizontal conduits not related to fractures (geometry can be a cylinder or a box) a distribution of vertical or horizontal passages representing karst morphologies can be specified. Parameters like (i) vertical, horizontal (x) and horizontal (y) minimum and maximum variations for vertical shafts, and (ii) lengths, radius, dip, and azimuth for lateral conduits can be used. Surfaces that are not necessarily related to a stratigraphic grid can be used as a reference for doline simulation and vug simulation. Density control can be achieved by selecting a surface attribute related to the same reference surface grid.

In some examples, modeling the epigenic karst features can be performed by a computing device. The computing device can receive input data (geological field data, generally obtained from outcrops analogs, seismic data, drone or other geological measurements). The computing device can select a geological object to be simulated. The computing device can populate object parameters according to a user interface parametrization panel that collects various information such as three-dimensional geometric scales.

The computing device can simulate a location of a desired object using a random point process, a regionalized point process, a cluster point process with appropriated density (number of points per volume), or any other suitable processes. Each populated location can include a seed for a karst feature (geological object) to be generated. The computing device can select a karst feature density, which can be computed from seismic attributes, from a reference surface, from a three-dimensional stratigraphic grid, or from other, populated three-dimensional volume. The computing device can simulate a three-dimensional, selected geological object and distribute the object as point sets in three-dimensional space. The computing device can perform the simulation until a number of elements selected using the user interface is reached according to density rules. The computing device can perform a karst simulation resulting from the union of point set clouds, three-dimensional meshes, and the like. The geometry and description parameters of epigenic karst geomorphological features and geo-statistical laws with intensity can be selected. The intensity can be used to locate seeds for a spatial distribution, as Poisson point process, regionalized Poisson, or Cox process, of a karst feature.

The above illustrative examples are given to introduce the reader to the general subject matter discussed herein and are not intended to limit the scope of the disclosed concepts. The following sections describe various additional features and examples with reference to the drawings in which like numerals indicate like elements, and directional descriptions are used to describe the illustrative aspects, but, like the illustrative aspects, should not be used to limit the present disclosure.

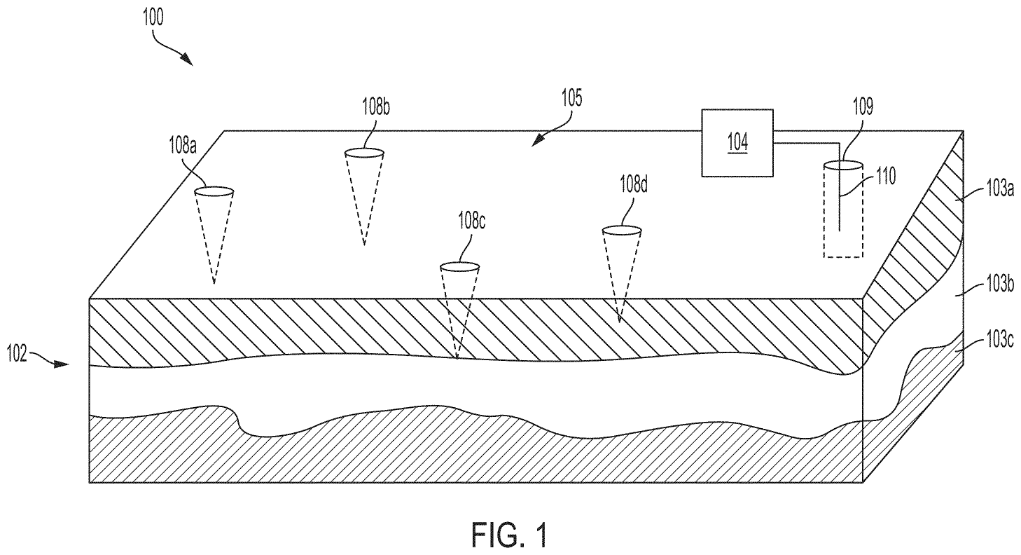

FIG. 1 is a perspective view of a karst formation 100 that includes a set of karst features 108a-d according to one example of the present disclosure. The karst formation 100 can be, can be included in, or can include a subterranean formation 102 in which the karst features 108a-d and a reference wellbore 109 are disposed or otherwise formed. Other features can be included with respect to the karst formation 100. The subterranean formation 102 may include a set of layers 103a-c that can include various carbonate rock formations, subterranean reservoirs, and other suitable components of subterranean formations. The reference wellbore 109 may be formed in the subterranean formation 102 for extracting various materials such as water, oil, various gases, or for other suitable purposes such as CO₂ storage.

As illustrated, the karst formation 100 includes four karst features 108a-d, but other suitable amounts of karst features 108 can be included in the karst formation 100. The karst features 108a-d may include dolines, vugs, fractures, caves, or other suitable karst features. In some examples, the karst features 108a-d may be similar (e.g., each of the karst features 108a-d may be dolines). In other examples, the karst features 108a-d may be different (e.g., the karst feature 108a may be a vug, the karst feature 108b may be a doline, the karst feature 108c may be a cave, the karst feature 108d may be a fracture, etc.). Other suitable amount or types of karst features 108 can be included in the karst formation 100.

A computing device 104 can be disposed at the surface 105 (or any other suitable location) of the subterranean formation 102. The computing device 104 can be communicatively coupled to a measuring device 110 (e.g., a fiber optic cable) for measuring or receiving data from the reference wellbore 109 or other suitable sources. The computing device 104 can include a processor and a memory that can store processor-executable instructions for performing various operations with respect to the reference wellbore 109 and the karst formation 100. For example, the computing device 104 can be used to simulate a fracture network and other suitable features with respect to the karst formation 100 based on fracture properties determined from received data about the reference wellbore 109 or other suitable sources. Additionally, the computing device 104 can apply the simulated fracture network along with fracture properties to model a fracture feature in an area of a planned, target wellbore in the karst formation 100. Accordingly, the karst formation 100 can be modeled with respect to planned, target wellbores without deploying the measuring device 110. In some examples, the computing device 104 can output one or more commands for adjusting wellbore operations, such as drilling operations, exploration operations, production operations, injection operations, and the like, with respect to the karst formation 100. For example, the commands may optimize or otherwise improve the performed wellbore operations. Additionally, the output from the computing device 104 can be used to address various challenges, such as water cut and lost circulation, associated with the wellbore operations.

One or more target wellbores (not shown) may be planned to be formed in the subterranean formation 102 (e.g., proximate to the reference wellbore 109 or in other suitable locations). The target wellbores may be planned to be formed near the reference wellbore 109, near one or more of the karst features 108a-d, or a combination thereof. Forming the target wellbores near the karst features 108a-d may present various challenges. For example, water cut in a drilling operation, lost circulation in a completion operation, and other similar or suitable challenges may be encountered. Modeling the karst features 108a-d prior to, or during, the wellbore operations can mitigate or prevent the challenges. For example, the modeled karst features 108 can be used to adjust a drilling operation to prevent a water cut, etc.

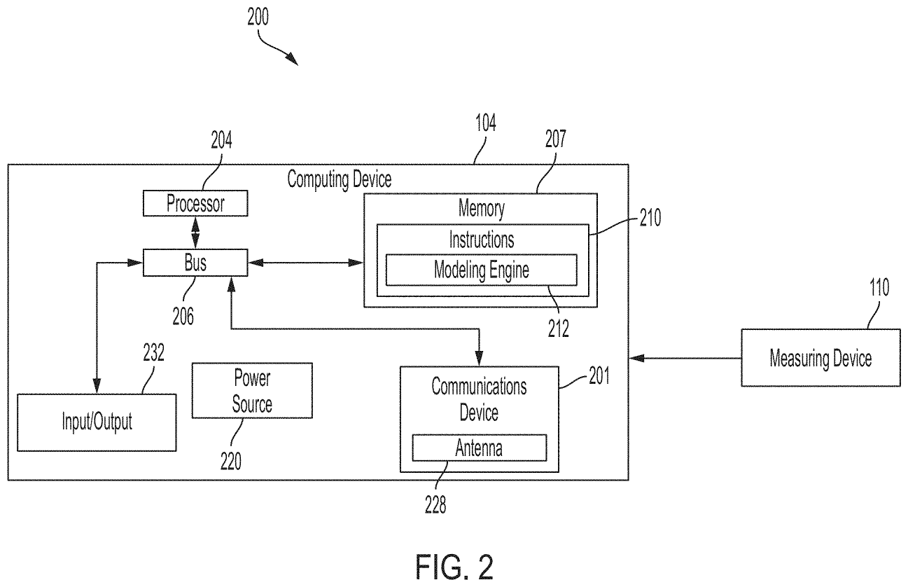

FIG. 2 is a block diagram of a computing system 200 for modeling a karst formation 100 according to one example of the present disclosure. The components shown in FIG. 2, such as the processor 204, memory 207, power source 220, and communications device 201, may be integrated into a single structure, such as within a single housing of the computing device 104. Alternatively, the components shown in FIG. 2 can be distributed from one another and in electrical communication with each other.

The computing system 200 may include the computing device 104. The computing device 104 can include a processor 204, a memory 207, and a bus 206. The processor 204 can execute one or more operations for modeling one or more karst features 108 of the karst formation 100. The processor 204 can execute instructions stored in the memory 207 to perform the operations. The processor 204 can include one processing device or multiple processing devices or cores. Non-limiting examples of the processor 204 include a Field-Programmable Gate Array (“FPGA”), an application-specific integrated circuit (“ASIC”), a microprocessor, etc.

The processor 204 can be communicatively coupled to the memory 207 via the bus 206. The non-volatile memory 207 may include any type of memory device that retains stored information when powered off. Non-limiting examples of the memory 207 may include EEPROM, flash memory, or any other type of non-volatile memory. In some examples, at least part of the memory 207 can include a medium from which the processor 204 can read instructions. A computer-readable medium can include electronic, optical, magnetic, or other storage devices capable of providing the processor 204 with computer-readable instructions or other program code. Non-limiting examples of a computer-readable medium include (but are not limited to) magnetic disk(s), memory chip(s), ROM, RAM, an ASIC, a configured processor, optical storage, or any other medium from which a computer processor can read instructions. The instructions can include processor-specific instructions generated by a compiler or an interpreter from code written in any suitable computer-programming language, including, for example, C, C++, C#, Java, etc.

In some examples, the memory 207 can include computer program instructions 210 for generating and applying a modeling engine 212. For example, the instructions 210 can include the modeling engine 212 that is executable by the processor 204 for causing the processor 204 to model the karst features 108. The modeling engine 212 can receive input data (e.g., from the measuring device 110 that can be communicatively coupled to the computing device 104) that can include fracture properties and point sets that can be used to project fracture features from the reference wellbore 109 in the karst formation 100. For example, the computing device 104 can receive data indicating fracture properties in the reference wellbore 109. The computing device 104 can use the input data, via the modeling engine 212, to determine a fracture geometry of the fracture network with respect to the reference wellbore 109. The computing device can use the modeling engine 212 to model fracture features and other features associated with the karst formation 100.

The computing device 104 can include a power source 220. The power source 220 can be in electrical communication with the computing device 104 and the communications device 201. In some examples, the power source 220 can include a battery or an electrical cable (e.g., a wireline). The power source 220 can include an AC signal generator. The computing device 104 can operate the power source 220 to apply a transmission signal to the antenna 228 to generate electromagnetic waves that convey data relating to the reference wellbore 109, the modeling engine 212, etc. to other systems. For example, the computing device 104 can cause the power source 220 to apply a voltage with a frequency within a specific frequency range to the antenna 228. This can cause the antenna 228 to generate a wireless transmission. In other examples, the computing device 104, rather than the power source 220, can apply the transmission signal to the antenna 228 for generating the wireless transmission.

In some examples, part of the communications device 201 can be implemented in software. For example, the communications device 201 can include additional instructions stored in memory 207 for controlling functions of the communication device 201. The communications device 201 can receive signals from remote devices and transmit data to remote devices. For example, the communications device 201 can transmit wireless communications that are modulated by data via the antenna 228. In some examples, the communications device 201 can receive signals (e.g. associated with data to be transmitted) from the processor 204 and amplify, filter, modulate, frequency shift, or otherwise manipulate the signals. In some examples, the communications device 201 can transmit the manipulated signals to the antenna 228. The antenna 228 can receive the manipulated signals and responsively generate wireless communications that carry the data.

The computing device 104 can additionally include an input/output interface 232. The input/output interface 232 can connect to a keyboard, a pointing device, a display, other computer input/output devices or any combination thereof. An operator may provide input using the input/output interface 232. Data relating to the reference wellbore 109, the karst formation 100, or a combination thereof can be displayed to an operator of a wellbore operation through a display that is connected to or is part of the input/output interface 232. The displayed values can be observed by the operator, or by a supervisor, of the wellbore operation, who can make adjustments to the wellbore operation based on the displayed values. Alternatively, the computing device 104 can, instead of displaying the values, automatically control or adjust the wellbore operation based on the modeled karst formation 100.

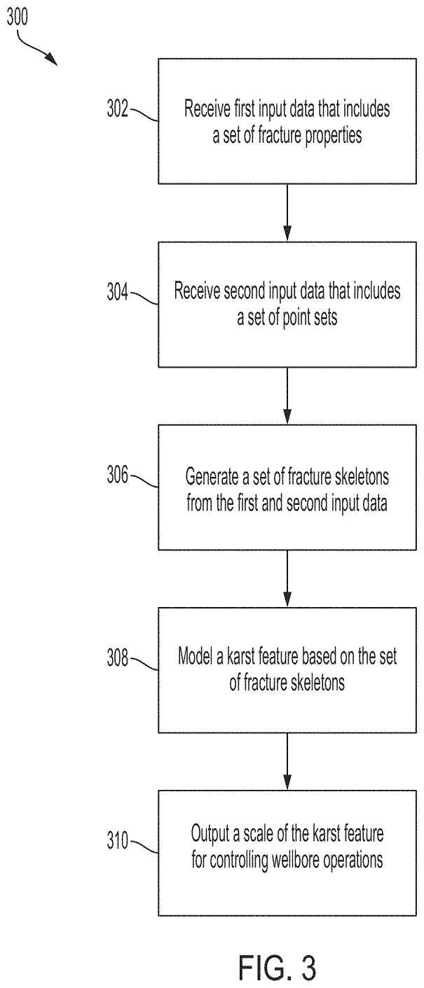

FIG. 3 is a flow chart of a process 300 for modeling a karst feature 108 according to one example of the present disclosure. At block 302, the computing device 104 receives first input data that includes a set of fracture properties. The first input data can be related to the karst formation 100 or any karst feature 108 thereof. The fracture properties can include aperture, permeability, porosity, or other fracture properties of the fracture network of the subterranean formation 102. In some examples, the measuring device 110 can measure (and include in the first input data) aperture, permeability, and porosity in the fracture network of the subterranean formation 102 via the reference wellbore 109. In some examples, the first input data can additionally include macro geometric information, such as length, width, dip direction, and dip angle, or other seismic-derived fracture properties of the karst formation 100.

At block 304, the computing device 104 receives second input data that includes point sets generated from a simulated fracture network. The second input data may indicate fracture features in the karst formation 100 and with respect to the reference wellbore 109. The second input data can be used to depict fracture features in or proximate to the reference wellbore 109. In some examples, the second input data can be a three-dimensional point set that is connected through vertices, edges, and faces that can form a three-dimensional geological object. For example, the second input data can be used to model caves as volumetric meshes. Additionally, the second input data can be used to generate or simulate tubular passages for representing morphologies, such as tubes, vertical shafts, horizontal passages, vugs of various sizes and orientations, abandoned phreatic caves, dolines, and the like.

At block 306, the computing device 104 generates set of fracture skeletons using the first input data and the second input data. The set of fracture skeletons can be used for simulating a set of three-dimensional geological objects that includes a fracture, a vug, a doline, a passage, a cave, or a combination thereof. In some examples, the point sets can be generated or otherwise received from the fracture geometry. In some examples, the first input data can be used to represent the three-dimensional geological objects as a set of triangular surface meshes.

In some examples, the point sets can be connected to create a graph that characterizes a connected component as part of a three-dimensional geological object. Additionally or alternatively, the three-dimensional geological object can be created by linking the points in the point sets of the second input data with a sufficient number of closest neighbors to obtain complete, connected objects. In other examples, the connected objects can be post-processed by reducing select edges using a minimum spanning tree algorithm or other suitable techniques. Another example of generating the set of fracture skeletons can include iteratively contracting the extremity branches of the connected objects along a main axis of the fracture. A polyline (e.g., a continuous line) of the connected objects can be obtained by further narrowing the extremity branches. In some examples, the polyline can be smoothed by adapting the discretization to the fracture size. The polyline may correspond to a fracture skeleton.

At block 308, the computing device 104 models one or more karst features 108 based on the fracture skeletons. The computing device 104 can use the first input data, the second input data, and the fracture skeleton for modeling the karst features 108. The modeled karst features 108 can include simulated images of the karst features 108, parameters relating to the karst features 108, and other suitable modeling information with respect to the karst features 108. In some examples, the fracture skeletons can be used to generate simulated models of the karst features 108. For example, the fracture skeletons can be used to simulate hypogenic caves. In another examples, the fracture skeleton can also be used to simulate fractures, vugs, dolines, and the like in the karst formation 100. In some examples, the karst formation 100 or any karst feature 108 thereof can be modeled using the fracture skeleton by a coarse method (e.g., in which primitive or otherwise basic objects are populated around the fracture skeleton), by a fine method (e.g., in which a cross-section associated with the fracture skeleton is slid along the fracture skeleton), other suitable methods, or any combination thereof.

The modeled karst features 108 can be used to improve one or more wellbore operations with respect to the karst formation 100. For example, the computing device 104 can use the modeled karst features 108 to determine a recovery efficiency to avoid water cut or other challenges with respect to forming a target wellbore in the subterranean formation 102. In some examples, the modeled karst features 108 can be scaled by using the point sets around each fracture skeleton to represent the volumetric hull of cavities associated with the karst features 108 with respect to the karst formation 100.

At block 310, the computing device 104 outputs one or more modeled karst features 108 for controlling a wellbore operation. For example, the karst features 108 can be used to project potential challenges associated with the wellbore operation. The challenges can include early water cut, lost circulation, recovery efficiency, etc. The computing device 104 can output command for controlling the wellbore operation in response to determining the challenges based on the modeled karst features 108. For example, the computing device 104 can be used to output a command to adjust parameters of a drilling operation, parameters of a completion operation, or the like for mitigating, preventing, or overcoming the challenges.

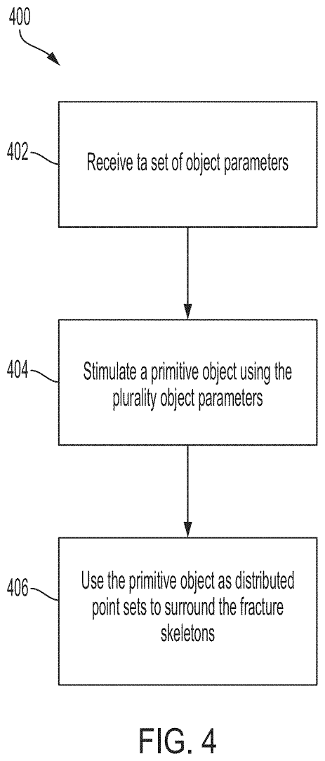

FIG. 4 is a flow chart of a process 400 for using one or more primitive objects to model a karst formation 100 according to one example of the present disclosure. At block 402, the computing device 104 receives a set of object parameters. Additionally or alternatively, the computing device 104 can receive one or more fracture skeletons. The object parameters, the fracture skeleton, or a combination thereof may relate to the karst formation 100, any karst features 108 thereof, etc. Additionally, or alternatively, the set of parameters can include various karst parameters, for examples, epigenic karst parameters and hypogenic karst parameters for use in simulating the primitive objects. The object parameters can include any other suitable parameters that can be used to model or simulate a primitive object. In some examples, the primitive object can be an object simulated or determined based on a skeleton (e.g., the fracture skeleton).

At block 404, the computing device 104 simulates one or more primitive objects in form of point sets to surround or cover at least one part of the fracture skeletons. In some examples, the primitive object can include one or more objects that can be used to model a karst feature 108 based on the fracture skeleton. For example, the point sets can indicate various basic objects that extend from, that encapsulate, or that otherwise relate to the fracture skeleton. In some examples, the primitive objects can include an ellipsoid, which can be assigned to each vertex of the fracture skeleton, and a cylinder, which can be assigned to each edge of the fracture skeleton. The respective parameters of size (e.g., ellipsoid and cylinder deformation radii) and orientation of the primitive objects or shapes can be formulated to fit the geological reality.

At block 406, the computing device 104 uses the primitive objects as distributed point sets to surround the fracture skeletons. For example, the primitive objects can be correlated to, or otherwise associated with, the distributed point sets. The computing device can generate (e.g., correlate) the distributed point sets from the primitive objects. In doing so, the computing device 104 may be configured to construct the karst formation 100, or any karst feature 108 thereof, by applying the distributed point sets to the primitive objects and connecting the point sets accordingly.

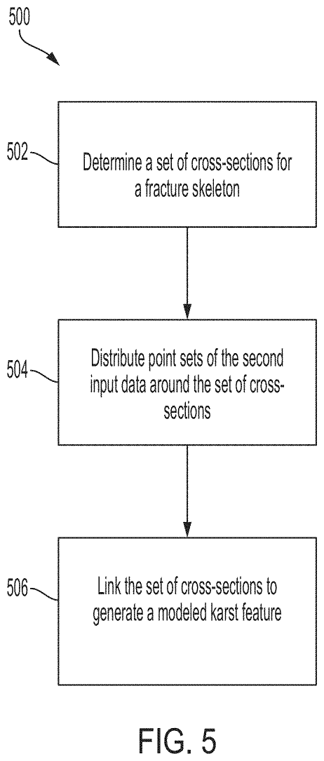

FIG. 5 is a flow chart of a process 500 for simulating a karst feature 108 of a karst formation 100 using cross-sections associated with fracture skeletons according to one example of the present disclosure. At block 502, the computing device 104 simulates cross-sections based on the fracture properties for the set of fracture skeletons. In some examples, the cross-sections can be based on the fracture properties at each skeleton vertex in the set of fracture skeletons. For example, the cross-sections can be elliptical cross-sections that are determined based on geological properties or attributes associated with the fracture skeleton.

At block 504, the computing device 104 distributes the point sets around the set of cross-sections. The cross-sections can be correlated to the point sets, and the computing device 104 can distribute (or otherwise assign) the point sets to the cross-sections. For example, the computing device 104 can assign one or more point sets to each elliptical cross-section for the fracture skeleton.

At block 506, the computing device 104 links the set of cross-sections by a sweeping process to generate a modeled karst feature 108. In some examples, the modeled karst feature 108 can include a volumetric cave or other suitable karst feature 108. The sweeping process may involve applying the cross-sections, including the point sets, along the length of the fracture skeleton to generate a three-dimensional representation of the karst feature 108. In some examples, the computing device 104 can distribute triangular surface meshes from the point sets around the set of cross-sections. Each triangle of the triangular surface mesh may include a center point, and stored data relating to geological attributes at locations corresponding to each triangle. For example, the geological attributes can include a permeability, a porosity, and the like. Each triangle can be displayed with a visual indication (e.g., color, size, distortion, etc.) of the geological attributes.

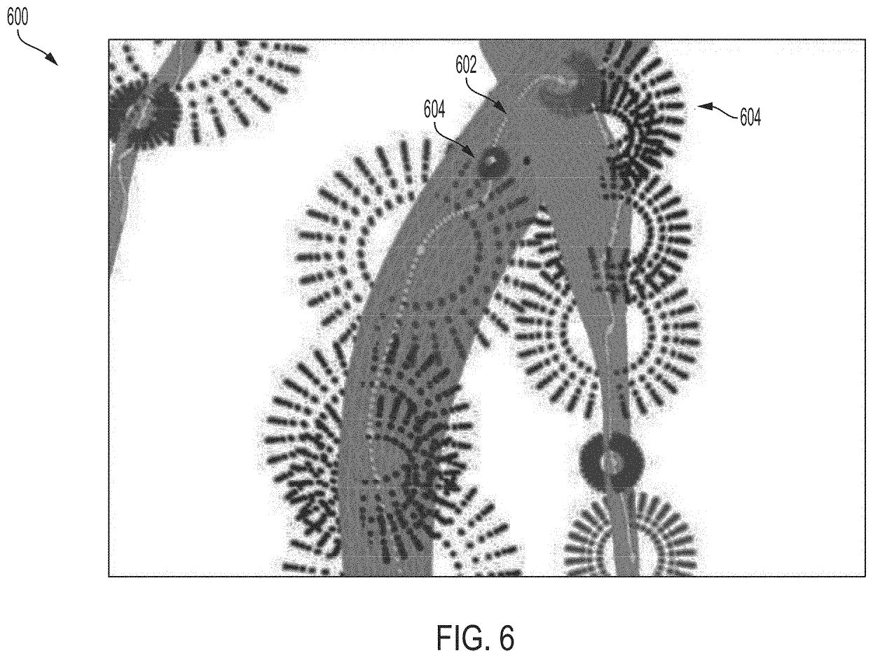

FIG. 6 is an example of a modeled result 600 of a primitive object 604 of a karst formation 100 according to one example of the present disclosure. The modeled result 600 includes a fracture skeleton 602 and primitive object 604 as in form of distributed point sets. The primitive object 604 may be formed by linking the point sets and may be ellipsoidal or cylindrical in shape. Other suitable primitive shapes can be used. In some examples, the modeled result 600 can be generated using the techniques described with respect to the process 400 of FIG. 4. The computing device 104 can simulate the primitive object 604 by using (e.g., applying) the primitive object 604 (i.e., distributed point sets) that correspond to the fracture skeleton 602) to generate the modeled result 600, which can represent one or more karst features 108 of a karst formation 100.

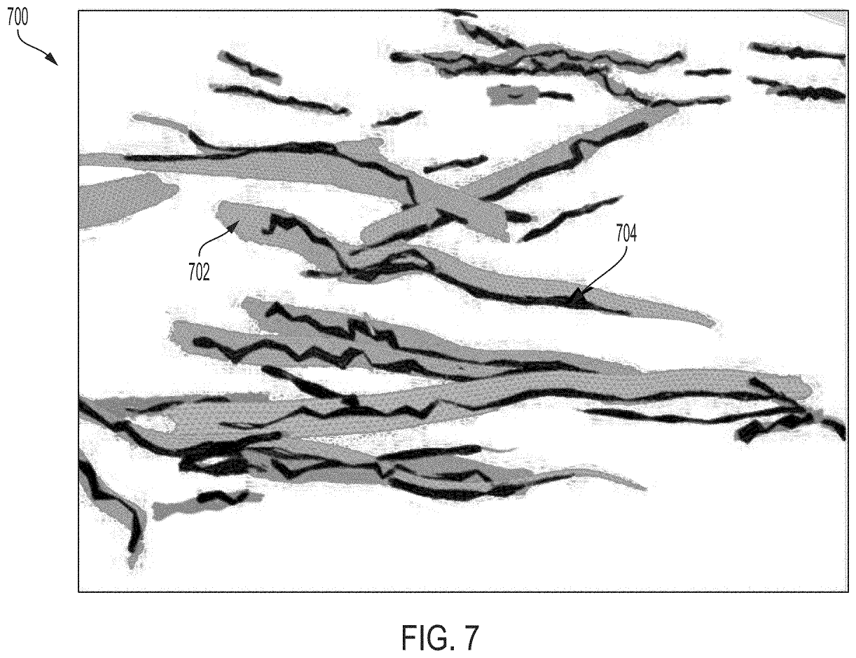

FIG. 7 is an example of a modeled result 700 of a karst feature 108 of a karst formation 100 using cross-sections according to one example of the present disclosure. The computing device 104 can simulate or otherwise generate a set of cross-sections for the set of fracture skeletons 704. For example, the computing device 104 can use fracture properties at each skeleton vertex in the set of fracture skeletons 704 to determine the cross-sections for generating a triangular mesh 702. The fracture properties can include permeability, porosity, aperture, or any other suitable fracture properties. The fracture properties can influence properties of the cross-sections. The properties can include size, location, and the like with respect to the triangular mesh, which can be used to represent a karst feature 108. The fracture properties can also be correlated to the centroid of each triangle in the triangular mesh 702 during the generation of fracture skeletons from the point sets.

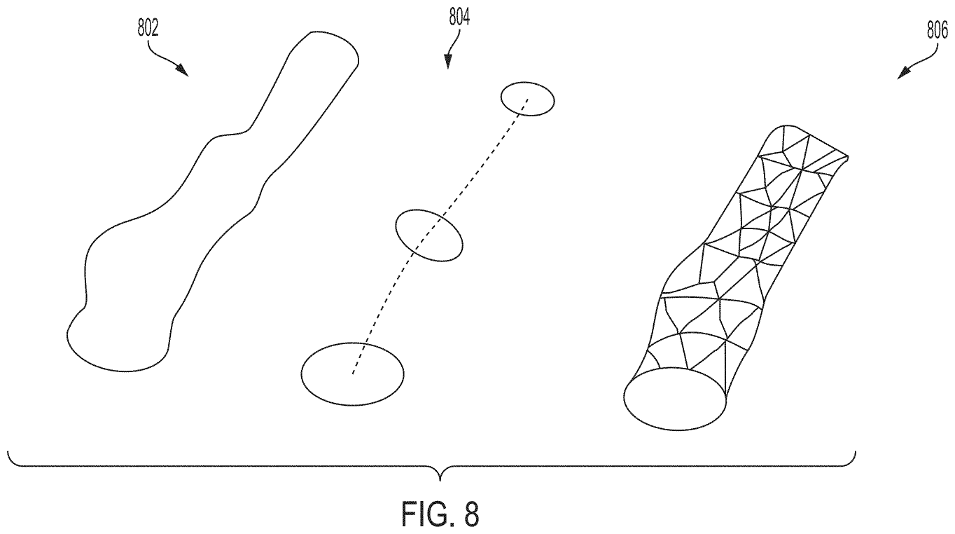

FIG. 8 is an example of a modeled karst feature according to one example of the present disclosure. The modeled karst feature can include or represent any suitable karst feature 108. The computing device 104 can generate or otherwise receive a lofted solid 802 that approximately corresponds to a karst feature 108. The computing device 104 can identify fracture skeleton vertices of the fracture skeleton 602 associated with the lofted solid 802 and can determine or otherwise receive a set of cross-sections 804 defining various fracture properties, such as aperture, permeability, and porosity, etc. The computing device 104 can link the cross-sections 804 together by a sweeping process along the fracture skeletons to generate the modeled karst feature, which can be represented as a three-dimensional geological object 806.

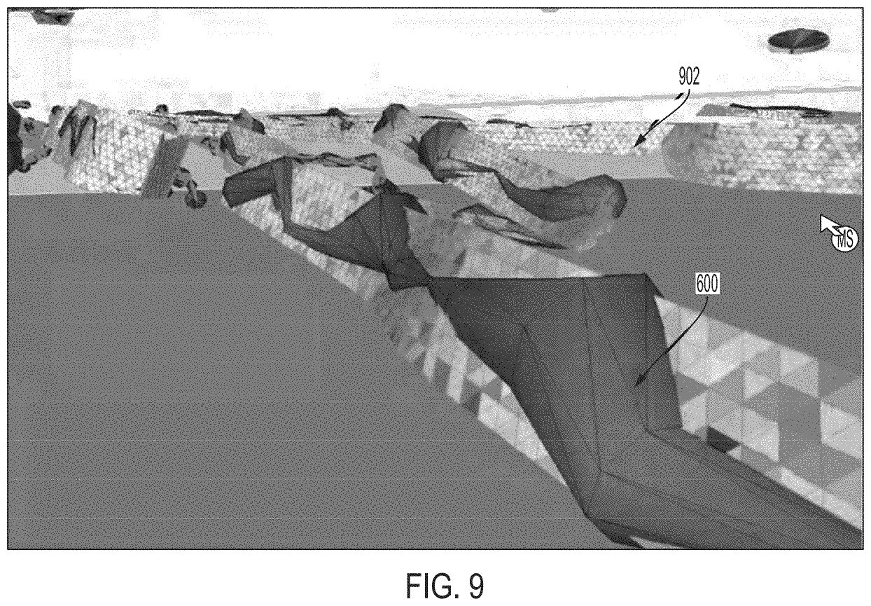

FIG. 9 is an example of a modeled karst feature based on a set of triangular meshes 902 according to one example of the present disclosure. The computing device 104 can generate the fracture skeleton to form the modeled result 600 600 and can generate the set of triangular meshes 902. In some examples, the computing device 104 can generate the triangular meshes 902 based on geological attributes associated with the fracture skeleton 602 at various locations (e.g., that correspond to a location of triangles of the triangular mesh 902). In one example, the fracture properties can be integrated into one or more triangles of the triangular mesh 902. The triangular mesh 902 can also include centroids corresponding to each triangle of the triangular mesh 902 during a point set initialization process. During the point set contraction process, the fracture properties can be held on points going through the same interpolation operations.

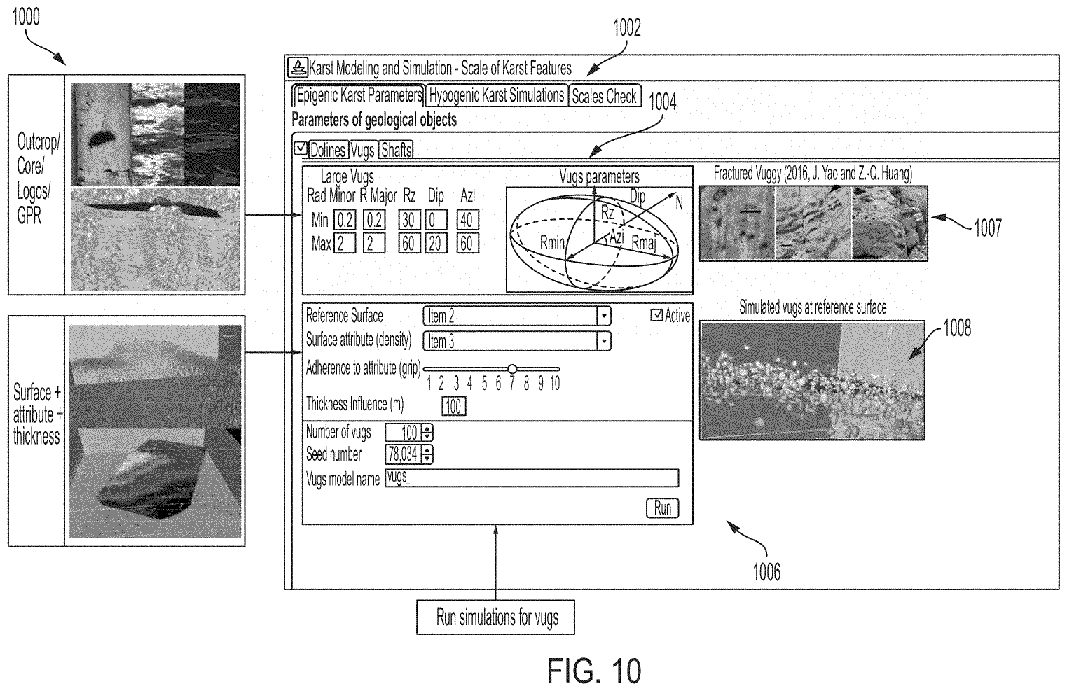

FIG. 10 is an example of a graphical user interface 1000 that can be used to model a karst formation 100 according to one example of the present disclosure. The user interface 1000 can include tabs 1002 and sub-tabs 1004. The tabs 1002 can correspond to various karst parameters. For example, the tabs 1002 can be used to select epigenic karst parameters, hypogenic karst parameters, or a scale check for use in simulating a three-dimensional geological object (e.g., one or more karst features 108). The sub-tabs 1004 can be used to scale various karst features 108 for a particular geological object. For example, the geological objects that can be scaled using the sub-tabs include vugs, shafts, dolines, and the like. The geological objects can be scaled to an unstructured grid for simulating the three-dimensional geological object. Additionally, the user interface 1000 can include a second panel 1006 that can be used to adjust various optional parameters, such as reference surface, surface density, thickness influence, or number of geological objects.

The user interface 1000 can include an interface that enables entities (e.g., users of the user interface 1000) to parametrize a karst formation simulation with various optional parameters. The optional parameters can include various epigenic karst parameters and hypogenic karst parameters. In one example, the user interface 1000 can be used to insert or to select the input data, geological objects (e.g. caves, vugs, fractures, dolines, or passages, etc.), fracture properties and filters for karst simulations.

In some examples, the graphical user interface 1000 can be used to receive the input data (e.g., geological field data, generally obtained from outcrops analogs, seismic data, drone or other geological measurements) via the tabs 1002 and to select geological objects to be simulated or modeled. Additionally, the object parameters can be input into the graphical user interface 1000 via the sub-tabs 1004, which can collect information such as three-dimensional geometrical scales, object variations, and scale variations. In some examples, the graphical user interface 1000 can simulate a location of a desired object using a random point process, a regionalized point process, a cluster point process with appropriated density (number of points per volume), or any other suitable processes. Each location can be a seed for the karst features or geological objects to be generated. Moreover, the graphical user interface 1000 can set a karst feature density that can be computed from seismic attributes, extracted reference surfaces, three-dimensional stratigraphic grids, or other, suitable populated three-dimensional volume. Additionally, some locations of objects can intersect or be proximate to fractures or other suitable stratigraphic grid feature or horizons (e.g., fractures or exposed surfaces).

In some examples, the graphical user interface 1000 can simulate a three-dimensional, selected geological object and distribute the selected object as point sets in three-dimensional space in a first display area 1007. Additionally, the graphical user interface 1000 can perform karst simulation with respect to a union of point set clouds and three-dimensional meshes in a second display area 1008, which can represent dissolutions and enlargements of fractures, vugs, dolines, passages, caves, or other suitable karst features using a three-dimensional model. In some examples, the user interface 1000 can be used to select the geometry and the parameters of one or more epigenic karst geomorphological features such as vugs, dolines, vertical shafts associated with meteoric water, carbonate with low vertical permeability-to-horizontal permeability ratio, geo-statistical laws with intensity, and the like. In some examples, the computing device 104 can also create a set of filters to simulate karst features based on a particular fracture direction, dip direction, dip angle, stratigraphic interval from the fracture network, and the like.

In some aspects, systems, methods, and non-transitory computer-readable mediums for modeling a karst feature are provided according to one or more of the following examples:

As used below, any reference to a series of examples is to be understood as a reference to each of those examples disjunctively (e.g., “Examples 1-4” is to be understood as “Examples 1, 2, 3, or 4”).

Example 1 is a system comprising: a processor; and a non-transitory computer-readable medium comprising instructions that are executable by the processor for causing the processor to perform operations comprising: receiving first input data that includes a plurality of fracture properties in a fracture network of a subterranean formation; receiving second input data that includes a plurality of point sets from a fracture geometry of the fracture network; generating a plurality of fracture skeletons from the first input data and the second input data; modeling a karst feature based on the plurality of fracture skeletons; and outputting the karst feature for controlling a wellbore operation.

Example 2 is the system of example 1, wherein the second input data comprises a plurality surface triangular meshes from the plurality of point sets.

Example 3 is the system of example 1, wherein the plurality of fracture properties comprises aperture, permeability, and porosity in the fracture network of the subterranean formation.

Example 4 is the system of example 1, wherein the operation of modeling a karst feature based on the plurality of fracture skeletons comprises: receiving a plurality of object parameters including size, major axis, and minor axis; simulating a primitive object using the plurality of object parameters; and using the primitive object as a plurality of distributed point sets to surround the plurality of fracture skeletons to represent the karst feature.

Example 5 is the system of example 1, wherein the operation of modeling a karst feature based on the plurality of fracture skeletons comprises: simulating a plurality of cross-sections for the plurality of fracture skeletons based on the plurality of fracture properties at each skeleton vertex in the plurality of fracture skeletons; distributing the plurality of point sets around the plurality of cross-sections; and linking the plurality of cross-sections by a sweeping process to generate a volumetric modeled cave representing the karst feature.

Example 6 is the system of example 1, wherein the operations further comprise refining the plurality of fracture skeletons by reducing and discarding selected edges of each skeleton of the plurality of fracture skeletons using a minimum spanning tree algorithm.

Example 7 is the system of example 1, wherein the operations further comprise generating a graphical user interface configured to: receive epigenic karst parameters and hypogenic karst parameters for use in simulating a three-dimensional geological object that includes a fracture, a vug, a doline, a passage, or a cave; and scale, using the epigenic karst parameters and the hypogenic karst parameters, the karst feature to a regular grid or an unstructured grid for simulating the three-dimensional geological object.

Example 8 is a method comprising: receiving first input data that includes a plurality of fracture properties in a fracture network of a subterranean formation; receiving second input data that includes a plurality of point sets from a fracture geometry of the fracture network; generating a plurality of fracture skeletons from the first input data and second input data; modeling a karst feature based on the plurality of fracture skeletons; and outputting the karst feature for controlling a wellbore operation.

Example 9 is the method of example 8, wherein the second input data comprises a plurality surface triangular meshes from the plurality of point sets.

Example 10 is the method of example 8, wherein the plurality of fracture properties comprises aperture, permeability, and porosity in the fracture network of the subterranean formation.

Example 11 is the method of example 8, wherein modeling a karst feature based on the plurality of fracture skeletons comprises: receiving a plurality of object parameters including size, major axis, and minor axis; simulating a primitive object using the plurality of object parameters; and using the primitive object as a plurality of distributed point sets to surround the plurality of fracture skeletons to represent the karst feature.

Example 12 is the method of example 8, wherein modeling a karst feature based on the plurality of fracture skeletons comprises: simulating a plurality of cross-sections for the plurality of fracture skeletons based on the plurality of fracture properties at each skeleton vertex in the plurality of fracture skeletons; distributing the plurality of point sets around the plurality of cross-sections; and linking the plurality of cross-sections by a sweeping process to generate a volumetric modeled cave representing the karst feature.

Example 13 is the method of example 8, wherein the operations further comprise refining the plurality of fracture skeletons by reducing and discarding selected edges of each skeleton of the plurality of fracture skeletons using a minimum spanning tree algorithm.

Example 14 is the method of example 8, wherein the operations further comprise generating a graphical user interface configured to: receive epigenic karst parameters and hypogenic karst parameters for use in simulating a three-dimensional geological object that includes a fracture, a vug, a doline, a passage, or a cave; and scale, using the epigenic karst parameters and the hypogenic karst parameters, the karst feature to a regular grid or an unstructured grid for simulating the three-dimensional geological object.

Example 15 is a non-transitory computer-readable medium comprising instructions that are executable by a processing device for causing the processing device to perform operations comprising: receiving first input data that includes a plurality of fracture properties in a fracture network of a subterranean formation; receiving second input data that includes a plurality of point sets from a fracture geometry of the fracture network; generating a plurality of fracture skeletons from the first input data and the second input data; modeling a karst feature based on the plurality of fracture skeletons; and outputting the karst feature for controlling a wellbore operation.

Example 16 is the non-transitory computer-readable medium of example 15, wherein the second input data comprises a plurality surface triangular meshes from the plurality of point sets.

Example 17 is the non-transitory computer-readable medium of example 15, wherein the plurality of fracture properties comprises aperture, permeability, and porosity in the fracture network of the subterranean formation.

Example 18 is the non-transitory computer-readable medium of example 15, wherein the operation of modeling a karst feature based on the plurality of fracture skeletons comprises: receiving a plurality of object parameters including size, major axis, and minor axis; simulating a primitive object using the plurality of object parameters; and using the primitive object as a plurality of distributed point sets to surround the plurality of fracture skeletons to represent the karst feature.

Example 19 is the non-transitory computer-readable medium of example 15, wherein the operation of modeling a karst feature based on the plurality of fracture skeletons comprises: simulating a plurality of cross-sections for the plurality of fracture skeletons based on the plurality of fracture properties at each skeleton vertex in the plurality of fracture skeletons; distributing the plurality of point sets around the plurality of cross-sections; and linking the plurality of cross-sections by a sweeping process to generate a volumetric modeled cave representing the karst feature.

Example 20 is the non-transitory computer-readable medium of example 15, wherein the operations further comprise refining the plurality of fracture skeletons by reducing and discarding selected edges of each skeleton of the plurality of fracture skeletons using a minimum spanning tree algorithm.

The foregoing description of certain examples, including illustrated examples, has been presented only for the purpose of illustration and description and is not intended to be exhaustive or to limit the disclosure to the precise forms disclosed. Numerous modifications, adaptations, and uses thereof will be apparent to those skilled in the art without departing from the scope of the disclosure.

What is claimed is:

1. A system comprising:
a processor; and
a non-transitory computer-readable medium comprising instructions that are executable by the processor for causing the processor to perform operations comprising:
receiving first input data that includes a plurality of fracture properties in a fracture network of a subterranean formation;
receiving second input data that includes a plurality of point sets from a fracture geometry of the fracture network;
generating a plurality of fracture skeletons from the first input data and the second input data;
modeling a karst feature based on the plurality of fracture skeletons; and
outputting the karst feature for controlling a wellbore operation.

2. The system of claim 1, wherein the second input data comprises a plurality surface triangular meshes from the plurality of point sets.

3. The system of claim 1, wherein the plurality of fracture properties comprises aperture, permeability, and porosity in the fracture network of the subterranean formation.

4. The system of claim 1, wherein the operation of modeling a karst feature based on the plurality of fracture skeletons comprises:
receiving a plurality of object parameters including size, major axis, and minor axis;
simulating a primitive object using the plurality of object parameters; and
using the primitive object as a plurality of distributed point sets to surround the plurality of fracture skeletons to represent the karst feature.

5. The system of claim 1, wherein the operation of modeling a karst feature based on the plurality of fracture skeletons comprises:
simulating a plurality of cross-sections for the plurality of fracture skeletons based on the plurality of fracture properties at each skeleton vertex in the plurality of fracture skeletons;
distributing the plurality of point sets around the plurality of cross-sections; and
linking the plurality of cross-sections by a sweeping process to generate a volumetric modeled cave representing the karst feature.

6. The system of claim 1, wherein the operations further comprise refining the plurality of fracture skeletons by reducing and discarding selected edges of each skeleton of the plurality of fracture skeletons using a minimum spanning tree algorithm.

7. The system of claim 1, wherein the operations further comprise generating a graphical user interface configured to:
receive epigenic karst parameters and hypogenic karst parameters for use in simulating a three-dimensional geological object that includes a fracture, a vug, a doline, a passage, or a cave; and
scale, using the epigenic karst parameters and the hypogenic karst parameters, the karst feature to a regular grid or an unstructured grid for simulating the three-dimensional geological object.

8. A method comprising:
receiving first input data that includes a plurality of fracture properties in a fracture network of a subterranean formation;
receiving second input data that includes a plurality of point sets from a fracture geometry of the fracture network;
generating a plurality of fracture skeletons from the first input data and second input data;
modeling a karst feature based on the plurality of fracture skeletons; and
outputting the karst feature for controlling a wellbore operation.

9. The method of claim 8, wherein the second input data comprises a plurality surface triangular meshes from the plurality of point sets.

10. The method of claim 8, wherein the plurality of fracture properties comprises aperture, permeability, and porosity in the fracture network of the subterranean formation.

11. The method of claim 8, wherein modeling a karst feature based on the plurality of fracture skeletons comprises:
receiving a plurality of object parameters including size, major axis, and minor axis;
simulating a primitive object using the plurality of object parameters; and
using the primitive object as a plurality of distributed point sets to surround the plurality of fracture skeletons to represent the karst feature.

12. The method of claim 8, wherein modeling a karst feature based on the plurality of fracture skeletons comprises:
simulating a plurality of cross-sections for the plurality of fracture skeletons based on the plurality of fracture properties at each skeleton vertex in the plurality of fracture skeletons;
distributing the plurality of point sets around the plurality of cross-sections; and
linking the plurality of cross-sections by a sweeping process to generate a volumetric modeled cave representing the karst feature.

13. The method of claim 8, further comprising refining the plurality of fracture skeletons by reducing and discarding selected edges of each skeleton of the plurality of fracture skeletons using a minimum spanning tree algorithm.

14. The method of claim 8, further comprising generating a graphical user interface configured to:
receive epigenic karst parameters and hypogenic karst parameters for use in simulating a three-dimensional geological object that includes a fracture, a vug, a doline, a passage, or a cave; and
scale, using the epigenic karst parameters and the hypogenic karst parameters, the karst feature to a regular grid or an unstructured grid for simulating the three-dimensional geological object.

15. A non-transitory computer-readable medium comprising instructions that are executable by a processing device for causing the processing device to perform operations comprising:
receiving first input data that includes a plurality of fracture properties in a fracture network of a subterranean formation;
receiving second input data that includes a plurality of point sets from a fracture geometry of the fracture network;
generating a plurality of fracture skeletons from the first input data and the second input data;
modeling a karst feature based on the plurality of fracture skeletons; and
outputting the karst feature for controlling a wellbore operation.

16. The non-transitory computer-readable medium of claim 15, wherein the second input data comprises a plurality surface triangular meshes from the plurality of point sets.

17. The non-transitory computer-readable medium of claim 15, wherein the plurality of fracture properties comprises aperture, permeability, and porosity in the fracture network of the subterranean formation.

18. The non-transitory computer-readable medium of claim 15, wherein the operation of modeling a karst feature based on the plurality of fracture skeletons comprises:
receiving a plurality of object parameters including size, major axis, and minor axis;
simulating a primitive object using the plurality of object parameters; and
using the primitive object as a plurality of distributed point sets to surround the plurality of fracture skeletons to represent the karst feature.

19. The non-transitory computer-readable medium of claim 15, wherein the operation of modeling a karst feature based on the plurality of fracture skeletons comprises:
simulating a plurality of cross-sections for the plurality of fracture skeletons based on the plurality of fracture properties at each skeleton vertex in the plurality of fracture skeletons;
distributing the plurality of point sets around the plurality of cross-sections; and
linking the plurality of cross-sections by a sweeping process to generate a volumetric modeled cave representing the karst feature.

20. The non-transitory computer-readable medium of claim 15, wherein the operations further comprise refining the plurality of fracture skeletons by reducing and discarding selected edges of each skeleton of the plurality of fracture skeletons using a minimum spanning tree algorithm.
